(19) United States
(12) Patent Application Publication
(10) Pub. No.: US 2026/0239912 A1
(43) Pub. Date: Aug. 13, 2026

(54) WAFER PROCESSING APPARATUS AND WAFER PROCESSING SYSTEM INCLUDING THE SAME

(71) Applicant: Samsung Electronics Co., Ltd., Suwon-si (KR)

(72) Inventors: Junhee LEE, Suwon-si (KR); Sungjun NOH, Suwon-si (KR); Kwangsung SON, Suwon-si (KR); Jonghyun JEON, Suwon-si (KR); Sunggil KANG, Suwon-si (KR); Chanyeong JEONG, Suwon-si (KR)

(21) Appl. No.: 19/309,834

(22) Filed: Aug. 26, 2025

(30) Foreign Application Priority Data
Feb. 11, 2025 (KR) 10-2025-0017324

(51) Int. Cl. H01L 21/67

(52) U.S. Cl. CPC H10P 72/0416; H10P 72/0414

(57) ABSTRACT

The present disclosure relates to a semiconductor wafer processing apparatus. The semiconductor wafer processing apparatus may include a bath configured to accommodate a liquid used to process the plurality of semiconductor wafers, a liquid supply nozzle configured to supply the liquid into the bath, a gas supply nozzle disposed below the plurality of semiconductor wafers and configured to supply a gas into the bath to generate bubbles with the liquid supplied into the bath, a first rod disposed above the gas supply nozzle, the first rod being configured to change a path of a portion of the bubbles generated by the gas and ascend within the bath along a first path, and a support connected to the bath and configured to support the plurality of semiconductor wafers in a configuration with the semiconductor wafers of the plurality of semiconductor wafers spaced apart from each other above the first rod.

### CROSS-REFERENCE TO RELATED APPLICATION

This application claims priority to Korean Patent Application No. 10-2025-0017324, filed in the Korean Intellectual Property Office on Feb. 11, 2025, the entire contents of which are hereby incorporated by reference.

### BACKGROUND

### Field

The present disclosure relates to a semiconductor wafer processing apparatus that processes a plurality of semiconductor wafers with a liquid, and to a semiconductor wafer processing system including the same.

### Description of Related Art

A semiconductor wafer processing apparatus for performing substrate surface treatment steps such as surface cleaning or thin-film etching (etching) at the same time for a batch of a plurality of semiconductor wafers may be used in semiconductor manufacturing.

While the liquid used to process a plurality of semiconductor wafers is supplied to the semiconductor wafer processing apparatus, a gas may be supplied to the semiconductor wafer processing apparatus to facilitate the liquid supply. However, the speed distribution of the gas supply may become unbalanced depending on the location within the semiconductor wafer processing apparatus, and process variation and contamination may worsen due to a recirculation flow. In addition, because bubbles generated by the gas may not be uniformly distributed, variation defects may occur in specific areas of a semiconductor wafer. Furthermore, because the diameters and ascending speeds of bubbles change according to the number of semiconductor wafers being processed, it may be difficult to maintain uniform process conditions.

The present disclosure relates to a semiconductor wafer processing apparatus and a semiconductor wafer processing system addressing the above problems.

The problems addressed by the present disclosure are not limited to those described above, and other problems not mentioned may be addressed by a semiconductor wafer processing apparatus of the present disclosure which will be clearly understood by those of ordinary skill in the art from the following description of the invention.

### SUMMARY

According to an embodiment of the present disclosure, a semiconductor wafer processing apparatus may include: a bath configured to a liquid used to process a plurality of semiconductor wafers; a liquid supply nozzle configured to supply the liquid into the bath; a gas supply nozzle disposed below the plurality of semiconductor wafers and configured to supply a gas into the bath to generate bubble with the liquid; and configured to change a path of a portion of the bubbles that are generated by the gas and ascend within the bath along a first path; and a support connected to the bath and configured to support the plurality of semiconductor wafers in a configuration with semiconductor wafers of the plurality of semiconductor wafers spaced apart from each other above the first rod.

According to another embodiment of the present disclosure, a semiconductor wafer processing system may include: a bath configured to a liquid used to process the plurality of semiconductor wafers; a support connected to the bath and configured to support the plurality of semiconductor wafers in a configuration with wafers of the plurality of semiconductor wafers spaced apart from one another; a liquid supply nozzle configured to supply the liquid into the bath; a gas supply nozzle disposed below the plurality of semiconductor wafers and configured to supply a gas into of the bath to generate bubbles with the liquid; a rod disposed above the gas supply nozzle, the rod being configured to change the path of bubbles that are generated by the gas and ascend within the bath along a first path that intercepts the rod; a driver configured to rotate the rod; and a control circuit configured to control the driver to rotate the rod to change the path of bubbles contacting the rod at a first time point from the first path to at least one of a second path and a third path, and change, at a second time different from the first time, the path of the portion the bubbles contacting the rod from the first path to at least one of a fourth path and a fifth path. The fourth path and the fifth path are different from the second path and the third path, respectively.

According to another embodiment of the present disclosure, a semiconductor wafer processing apparatus may include: a bath configured to contain a liquid used to process a plurality of semiconductor wafers; a gas supply nozzle configured to supply a gas into the bath through a gas supply hole; a liquid supply nozzle configured to supply a liquid into the bath in a direction toward the gas supply hole, wherein the gas causes bubbles to form in the liquid; a rod disposed above the gas supply nozzle and configured to change the path of a portion of the bubbles that ascend within the bath; plates disposed within the bath at an upper portion of the bath; guides disposed on surfaces of the plates and configured to guide bubbles ascending in the bath to move outward from the bath; and a support connected to the bath and configured to support the plurality of semiconductor wafers in a configuration with semiconductor wafers of the plurality of semiconductor wafers spaced apart from each other with a side surface of each of the plurality of semiconductor wafers being disposed spaced apart from the plates by a predetermined gap, and an planar surface of each of the plurality of semiconductor wafers being parallel to the guides.

According to various embodiments of the present disclosure, because the rod selectively disperses or changes the path of bubbles, it may prevent the bubbles from concentrating in a particular region and may provide a uniform flow across the entire semiconductor wafer surface.

According to various embodiments of the present disclosure, because the liquid supply nozzle is arranged to face the gas supply hole and actively adjust the diameters of bubbles, the cleaning effect and process uniformity may be improved.

According to various embodiments of the present disclosure, by controlling the rotation of the rod so that bubbles spread along multiple paths, process variation may be reduced, and if necessary for a specific region, a concentrated flow may be induced to improve process efficiency.

According to various embodiments of the present disclosure, by guiding bubbles ascending along the side surfaces of the plurality of semiconductor wafers outward using the guide and the plate, the flow difference between the center portion and the peripheral portion may be alleviated, and the process uniformity may be improved.

According to various embodiments of the present disclosure, by supplying liquids with different flow rates through multiple liquid supply nozzles, the removal efficiency of contaminants generated on the semiconductor wafer surface may be enhanced, and contamination accumulation due to recirculation flow may be suppressed.

According to various embodiments of the present disclosure, because the drain hole effectively discharges overflowing liquid and by-products, contamination spread during the process may be reduced, and process reliability may be improved by resupplying the liquid that has undergone an external purification process.

The benefits and effects of the present disclosure are not limited to those described above, and may be more clearly understood in the course of describing specific embodiments of the present disclosure.

### BRIEF DESCRIPTION OF THE DRAWINGS

FIG. 1 is a perspective view illustrating a semiconductor wafer processing apparatus.

FIG. 2 illustrates a plan view of the semiconductor wafer processing apparatus.

FIG. 3 is a cross-sectional view illustrating a region taken along line I-I′ of FIG. 2.

FIG. 4 is a cross-sectional view illustrating a region taken along line II-II′ of FIG. 2.

FIG. 5 is a block diagram illustrating an example of a semiconductor wafer processing system according to an embodiment of the present disclosure.

FIGS. 6A and 6B are diagrams illustrating bubble flow resistance in a bath according to the spacing between semiconductor wafers and the size of the bubbles.

FIGS. 7A and 7B are diagrams illustrating an example in which the size of the bubbles within the bath is adjusted.

FIG. 8 is a diagram illustrating an example of the distribution of bubbles in the interior of the bath according to the position.

FIGS. 9A through 9E are diagrams illustrating an example in which the path of the bubbles is changed by a rod.

FIG. 10 illustrates an example in which the rod and the support are integrated.

FIG. 11 is a diagram showing a tendency that flow resistance increases toward the center of the semiconductor wafer and thus flow speed decreases accordingly.

FIG. 12 is a diagram illustrating an example of guiding the bubbles by using a guide and a plate.

### DETAILED DESCRIPTION

The present disclosure now will be described more fully hereinafter with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. Items described in the singular herein may be provided in plural, as can be seen, for example, in the drawings. Thus, the description of a single item that is provided in plural should be understood to be applicable to the remaining plurality of items unless context indicates otherwise. The language of the claims should be referenced in determining the requirements of the invention.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Terms such as “same,” “equal,” “planar,” “coplanar,” “parallel,” and “perpendicular,” as used herein encompass identicality or near identicality including variations that may occur resulting from conventional manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

In the following description, a wafer may refer to a semiconductor wafer. A semiconductor wafer include a base substrate (an initial substrate) formed of and/or including a crystalline semiconductor material on which additional layers are formed and patterned to form semiconductor devices. Typical examples of semiconductor materials of the substrate are: Group IV materials, such as Si, C, or Ge, or alloys of these such as SiC or SiGe; Group II-VI compounds (including binary, ternary, and quaternary forms), e.g., compounds formed from Group II materials such as Zn, Mg, Be or Cd and Group VI materials such as Te, Se or S, such as ZnSe, ZnSTe, or ZnMgSTe; and Group III-V compounds (including binary, ternary, and quaternary forms), e.g., compounds formed from Group III materials such as In, Al, or Ga and group V materials such as As, P, Sb or N, such as InP, GaAs, GaN, InAlAs, AlGaN, InAlGaAs, etc.

In the following description, when referring to a wafer, a bottom or top surface refers to the planar surface of the wafer which is typically normal to a vertical direction during fabrication processes. A side surface of the wafer refers to a curved surface of the wafer extending between the top and bottom surface of the wafer. When referring to the wafer inside of a bath, lower and upper may be relative to the bottom and top ends of the bath, respectively.

In the present disclosure, “each item of a plurality of items” may refer to each item of all or a portion of the plurality of items. For example, “each wafer of a plurality of wafers” may refer to each wafer of all of the plurality of wafers or each wafer of a portion of the plurality of wafers.

In the present disclosure, “path” may refer to a specific physical/spatial trajectory or spatial range that bubbles (or a liquid, or other flowing materials, etc.) may move or flow through from one location to another, and it is not limited to the trajectory up to a particular spatial point but may encompass the entire two-dimensional to three-dimensional region of possible movement in which straight lines, curves, branches, merges, etc. can be set. In addition, “path” is used in a sense that includes not only the actual dynamic trajectory through which bubbles move but also a total space where the direction or dispersion pattern of bubble movement may vary. For example, a path may include a virtual movement region determined by the flow of a fluid or external force, as well as a structurally restricted channel or pipe.

As used herein, the term “integrally formed” or “one-piece type” may refer to components formed together as a single structure such that the single structure is not constructed to be disassembled into separate components.

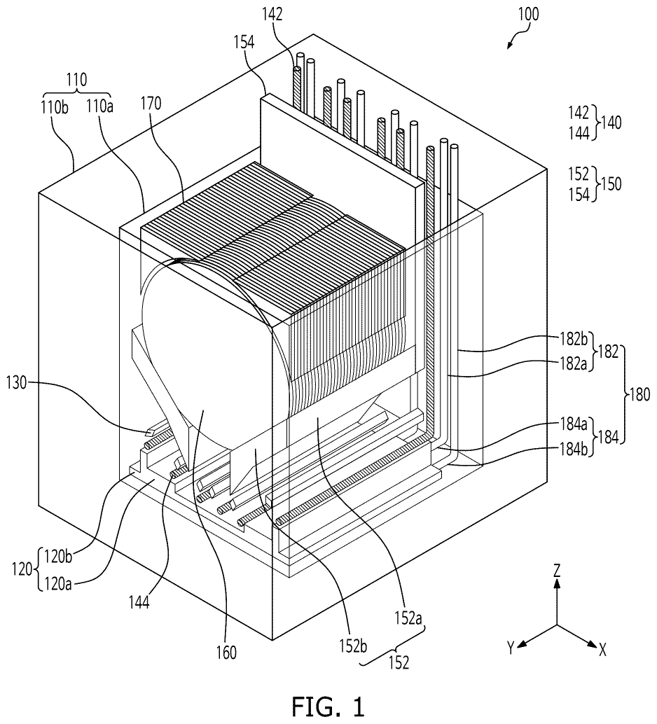

Hereinafter, various embodiments of the present disclosure will be described with reference to FIGS. 1 through 12. Throughout the entire specification, the same reference numerals may refer to the same elements.

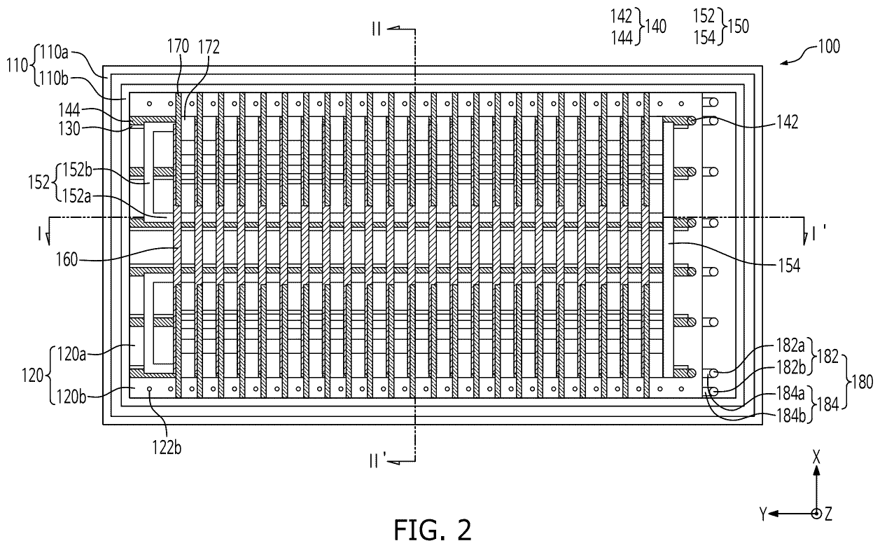

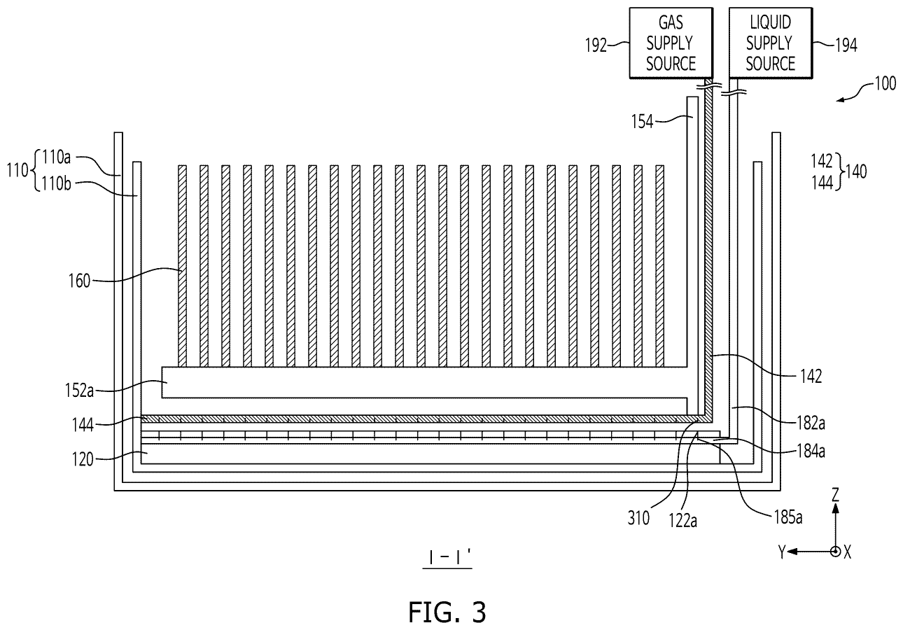

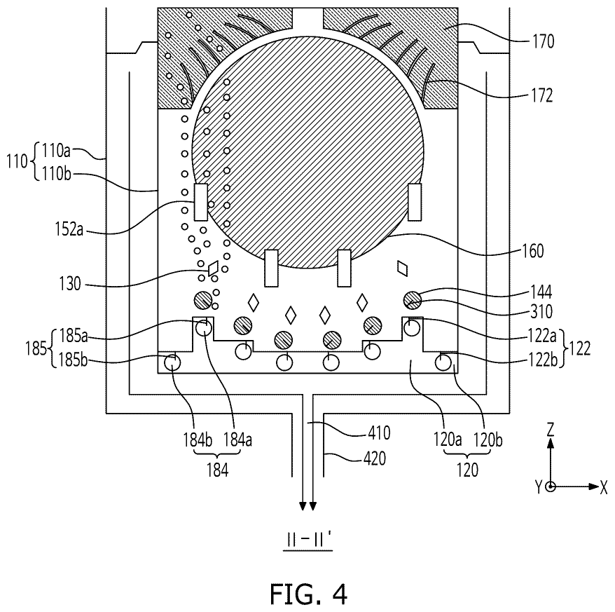

FIG. 1 is a perspective view of a wafer processing apparatus 100, FIG. 2 is a plan view of the wafer processing apparatus 100, FIG. 3 is a cross-sectional view illustrating a region taken along line I-I′ of FIG. 2, and FIG. 4 is a cross-sectional view illustrating a region taken along line II-II′ of FIG. 2.

A wafer processing apparatus 100 may perform various processes (for example, wet processes) for a wafer 160. For example, the wafer processing apparatus 100 may perform a cleaning process for a plurality of wafers 160.

By performing a cleaning process on the plurality of wafers 160 using the wafer processing apparatus 100, oxides, organic materials, or metallic impurities on the surfaces of the plurality of wafers 160 may be removed. While the plurality of wafers 160 are being processed, some components of the wafer processing apparatus 100 may support the wafers 160 and some may supply a liquid and a gas to generate a flow of cleaning fluid, so that the process of the wafers 160 proceeds efficiently. Hereinafter, configurations of the wafer processing apparatus 100 for processing a plurality of wafers 160 will be described in detail.

A bath 110 may provide a space in which a plurality of wafers 160 are accommodated and a wet process may be performed. The bath 110 may contain a liquid used to process the plurality of wafers 160.

The bath 110 may include an outer bath 110a and an inner bath 110b. The outer bath 110a may form the overall outer structure, and the inner bath 110b may accommodate the liquid used to process the plurality of wafers 160.

The inner bath 110b and the outer bath 110a may be spaced apart from each other by a certain distance. For example, the inner bath 110b and the outer bath 110a may be spaced apart from each other by a certain distance in each of the x, y, and/or z directions. Through the space between the inner bath 110b and the outer bath 110a, the liquid overflowing from the inner bath 110b may flow into the outer bath 110a.

The wafer processing apparatus 100 may further include a cover disposed above the bath 110 so as to prevent contamination or evaporation of the liquid or contamination of the wafer 160 or the like from the external environment. For example, the cover may be formed to cover the entire upper open surface of the outer bath 110a and may be coupled to one edge portion of the upper portion of the outer bath 110a by using a connecting member such as a hinge. In this case, an upper surface of a plate 170 may be attached to the cover and fixed to the cover so as to be positioned adjacent to the wafer 160 when the cover is closed.

In the wafer processing apparatus 100, the plurality of wafers 160 may be arranged spaced apart from each other. For example, the plurality of wafers 160 may be placed at a certain interval (for example, 5 mm). The distance between each of the plurality of wafers 160 may be narrowed or widened depending on the number of wafers 160 to be accommodated in the wafer processing apparatus 100.

A support 150 may be configured to support the plurality of wafers 160. The support 150 may support the plurality of wafers 160 to be spaced apart from each other. For example, the support 150 may support (for example, fix) the plurality of wafers 160 from below the plurality of wafers 160. For example, the support 150 may have support surfaces that contact wafers 160 loaded in the bath 101 to support the wafers 160. The support 150 (e.g., the support surfaces) may have various dimensions and mechanisms depending on the number and shape of the wafers 160 to be accommodated in the bath 110. Additionally, the support 150 may have a lifting function and/or a rotating function so as to facilitate loading the wafers 160 into the bath 110 or unloading the wafers 160 from the bath 110. For example, the support 150 may have an actuator that may raise or rotate the support 150 relative to the bath 110.

The support 150 may include a first support 152 and a second support 154. The first support 152 and the second support 154 may each be formed in a one-piece type (e.g., a single body) or an assembled type (e.g., formed of multiple bodies secured to one another), without limitation. In some embodiments, the first support 152 and the second support 154 may be formed together as a one-piece type.

The first support 152 may be formed and arranged in the inner bath 110b so as to hold the plurality of wafers 160 at a predetermined orientation or to allow a limited range of movement.

The first support 152 may include a lower support 152a and a cross member 152b. The lower support 152a and the cross member 152b may be formed as a one-piece type or an assembled type, but are not limited thereto. The lower support 152a may be formed so as to extend in the same direction in which the plurality of wafers 160 are spaced apart (or in a direction perpendicular to the top and bottom surfaces of the wafers) (for example, the y direction). The lower support 152a may be provided in a sufficient number (for example, four) to restrict left-right movement (for example, x-direction movement) of the plurality of wafers. The cross member 152b may extend in a direction perpendicular to the direction in which the plurality of lower supports 152a extend, thereby providing structural stability of the first support 152 by fixing the relative positions of the plurality of lower supports 152a.

The second support 154 may be formed to allow only limited movement of the plurality of wafers 160 in the y direction, or to disallow movement in the y direction. Although the second support 154 is shown as being disposed on one side of the inner bath 110b, it is not limited thereto, and may be disposed on one or more surfaces of the inner bath 110b. For example, the second support 154 may include multiple supports disposed on surfaces of the inner bath 110b that face each other.

A liquid supply unit 180 may supply a liquid for processing the plurality of wafers 160 into the inner bath 110b. The liquid supply unit 180 may include a liquid supply pipe 182 and a liquid supply nozzle 184.

Referring to FIGS. 1 through 3, the liquid supply pipe 182 may be formed to extend in a direction perpendicular to the bottom surface of the bath 110 (for example, the z direction), but is not limited thereto. The liquid supply pipe 182 may be connected to a liquid supply source 194 so as to receive the liquid from the liquid supply source 194. For example, the liquid supply source 194 may be a tank containing the liquid or a pipe connected to a source of the liquid.

The liquid supply nozzle 184 may be connected to the liquid supply pipe 182 and receive the liquid from the liquid supply pipe 182. The liquid supply nozzle 184 may be formed to extend in the same direction (for example, the y direction) in which the plurality of wafers 160 are spaced apart, but is not limited thereto. For instance, the liquid supply nozzle 184 may be formed to extend in an oblique direction (for example, intersecting the x direction and/or the y direction).

Referring to FIGS. 1 and 3, a liquid supply guide 120 may be disposed on a lower portion (for example, an upper surface of the bottom of the inner bath 110b) of the inner bath 110b so as to cover the liquid supply nozzle 184. The liquid supply guide 120 may guide the flow of the liquid or reduce turbulence when the liquid is introduced into the inner bath 110b through the liquid supply nozzle 184.

Referring to FIGS. 1, 3, and 4, the liquid supply guide 120 may be divided into a first portion 120a and a second portion 120b. The first portion 120a of the liquid supply guide 120 may refer to a portion disposed on the inner side of the liquid supply guide 120 extending toward the plurality of wafers 160 and disposed below the plurality of wafers 160, and the second portion 120b of the liquid supply guide 120 may refer to a portion disposed on the outer side of the liquid supply guide extending away from the plurality of wafers 160 and disposed below the plurality of wafers 160.

Referring to FIG. 4, a plurality of first liquid supply holes 185a may be formed in the first portion 120a of the liquid supply guide 120 to guide the liquid from the liquid supply to the upper side of the first portion 120a, and a plurality of second liquid supply holes 185b may be formed in the second portion 120b of the liquid supply guide 120 to guide the liquid from the liquid supply to the upper side of the second portion 120b.

The liquid supply nozzle 184 may supply the liquid into the interior of the bath 110. For example, referring to FIGS. 3 and 4, the liquid supply nozzle 184 may supply the liquid from the liquid supply pipe 182 into the interior of the bath 110 through a plurality of liquid supply holes 185 formed in the liquid supply nozzle 184. The liquid injected by the liquid supply nozzle 184 may include various wafer-processing liquids, such as a phosphoric acid solution and/or a cleaning solution. Referring to FIGS. 1 and 3, the liquid may be supplied from the liquid supply source 194 connected to the liquid supply unit 180 and recirculated, or may be newly introduced from outside the wafer processing apparatus 100.

Referring to FIGS. 1 and 2, the liquid supply pipe 182 may include a first liquid supply pipe 182a and a second liquid supply pipe 182b, and the liquid supply nozzle 184 may include a first liquid supply nozzle 184a connected to the first liquid supply pipe 182a and a second liquid supply nozzle 184b connected to the second liquid supply pipe 182b. Each of the first liquid supply nozzle 184a and second liquid supply nozzle 184b may function as a manifold for distributing the liquid to outlets of the nozzles.

The first liquid supply nozzle 184a may be disposed below the plurality of wafers 160. The first liquid supply nozzle 184a may be housed in the first portion 120a of the liquid supply guide 120. The second liquid supply nozzle 184b may be disposed below the plurality of wafers 160 and may be disposed away from the plurality of wafers 160 relative to the first liquid supply nozzle. The second liquid supply nozzle 184b may be housed in the second portion 120b of the liquid supply guide 120.

Each of the plurality of first liquid supply nozzles 184a may be arranged such that it is spaced by the same distance in the vertical direction (for example, the z direction) from corresponding gas supply nozzles 1444 of the plurality of gas supply nozzles 144, and the liquid supply guide 120 may be formed in a stepped shape accordingly, though it is not limited thereto.

In instances in which the flow rate of the liquid supplied by the plurality of first liquid supply nozzles 184a alone is insufficient for the flow rate required by the wafer processing, the second liquid supply nozzle 184b may supply additional liquid into the bath 110 (e.g., the liquid may be supplied by only the first liquid supply nozzles 184a or both the first and second liquid supply nozzles 184b).

Referring to FIG. 4, the liquid supply nozzle 184 may inject liquid into the inner bath 110b through the liquid supply holes 185. Referring to FIGS. 3 and 4, the liquid supply holes 185 may include a plurality of first liquid supply holes 185a and a plurality of second liquid supply holes 185b. The plurality of first liquid supply holes 185a may be holes formed in the first liquid supply nozzle 184a, and the plurality of second liquid supply holes 185b may be holes formed in the second liquid supply nozzle 184b.

The liquid supply holes 185 may be connected to guide holes 122 formed in the liquid supply guide 120. The plurality of first liquid supply holes 185a may supply liquid into the inner bath 110b through the plurality of first guide holes 122a formed in the first portion 120a of the liquid supply guide 120, and the plurality of second liquid supply holes 185b may supply liquid into the inner bath 110b through the plurality of second guide holes 122b formed in the second portion 120b of the liquid supply guide 120. The plurality of first liquid supply holes 185a and the plurality of second liquid supply holes 185b may be formed at regular intervals (for example, at regular intervals in the y direction), but are not limited thereto.

The first liquid supply nozzle 184a and the second liquid supply nozzle 184b may supply the liquid into the inner bath 110b at different flow speeds or flow rates. In an embodiment, a first diameter of the first liquid supply hole 185a, which supplies the liquid into the interior of the bath 110 from the first liquid supply nozzle 184a, may be smaller than a second diameter of the second liquid supply hole 185b, which supplies the liquid into the interior of the bath 110 from the second liquid supply nozzle 184b. Thus, the flow rate of the liquid supplied through the second liquid supply hole 185b may be larger than the flow rate of the liquid supplied through the first liquid supply hole 185a, and the first and second liquid supply nozzles 184a and 184b may supply the liquid into the inner bath 110b at different flow speeds or flow rates.

A gas supply unit 140 may include a gas supply pipe 142 and a gas supply nozzle 144.

The gas supply pipe 142 may be formed to extend in a direction perpendicular to the bath 110 (for example, the z direction), but is not limited thereto. The gas supply pipe 142 may be connected to a gas supply source 192 (for example, a gas generator, a gas cylinder, a gas tank, etc.) and receive gas from the gas supply source 192.

The gas supply nozzle 144 may be connected to the gas supply pipe 142 to receive the gas from the gas supply pipe 142 and may supply the gas into the interior of the bath 110. The gas supply nozzle 144 may be disposed below the plurality of wafers 160. The gas supply nozzle 144 may be formed to extend in the same direction (for example, the y direction) in which the plurality of wafers 160 are spaced apart, but is not limited thereto. For example, the gas supply nozzle 144 may be formed to extend in an oblique direction (for example, intersecting the x direction and/or the y direction). The gas supply nozzle 144 may function as a manifold for distributing gas supplied by the gas supply nozzle 144.

The plurality of gas supply nozzles 144 may be arranged so that, in the vertical direction (for example, the z direction), they maintain the same distance from the plurality of wafers 160. For example, cross-sections of the plurality of gas supply nozzles 144 may lie on an imaginary trajectory having the same curvature as the lower surfaces of the plurality of wafers 160 when loaded in the bath (e.g., the edge of a wafer when loaded as shown in FIG. 1). The wafer processing apparatus 100 may generate bubbles by passing the gas through the liquid. Once bubbles are generated, the ascending speed of the bubbles gradually starts to increase, and continues to increase until reaching a terminal velocity. As such, a consistent speed at which the bubbles reach the wafer 160 may be maintained.

Referring to FIGS. 1 and 3, the gas delivered through the gas supply pipe 142 may be supplied into the bath 110 through a gas supply hole 310 of the gas supply nozzle 144. The gas supplied from the gas supply source 192 may be an inert gas or another gas selected to meet the characteristics of the wafer process. The gas sprayed from the gas supply nozzle 144 may contact the liquid of the inner bath 110b, forming bubbles within the bath 110. Referring to FIG. 1, the gas supply nozzle 144 may be disposed adjacent to the lower portion of the bath 110 so that bubbles move upward from below the wafer 160. Thus, bubbles generated from the gas supply unit 140 may allow the liquid within the bath 110 to move smoothly, thereby accelerating processing of the plurality of wafers 160.

A rod 130 may be formed to change the path of bubbles ascending within the bath 110, the bubbles being generated by the gas supply unit 140.

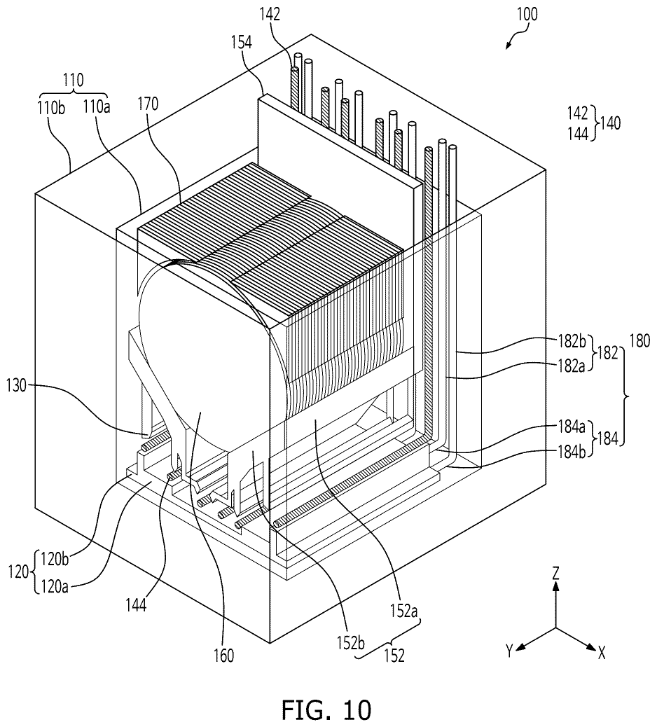

The rod 130 may be disposed above the gas supply nozzle 144 and below the plurality of wafers 160. The rod 130 may be formed integrally with the support 150 and extend from the lower portion of the support 150. This will be described later with reference to FIG. 10.

Bubbles that reach the rod 130 collide with the rod 130 and slow down. Because a sufficient distance between the rod 130 and the wafer 160 needs to be ensured to allow the bubbles to maintain their ascending speed, the rod 130 should also be spaced apart from the gas supply nozzle 144 by at least a minimum distance required for stabilizing the movement of the bubbles generated from the gas supply nozzle 144. For example, the distance between the rod 130 and the gas supply nozzle 144 may be determined as a multiple (for example, four-or five-fold) of a bubble diameter.

The rod 130 may have a polygonal cross section. The polygonal cross section of the rod 130 may be a rounded polygon cross section, in which at least some vertices have a certain curvature, or a general polygon cross section in which no vertices have curvature. In the present specification, “polygonal cross section” may be understood to include both a general polygonal cross section and a rounded polygon cross section. In an embodiment, the cross section of the rod 130 may be formed in a rhombus shape. The first diagonal and the second diagonal of the rhombus shape may be formed to have different lengths from each other.

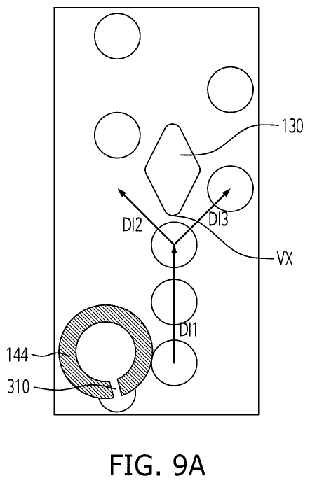

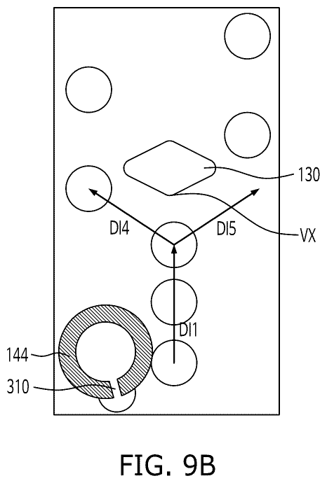

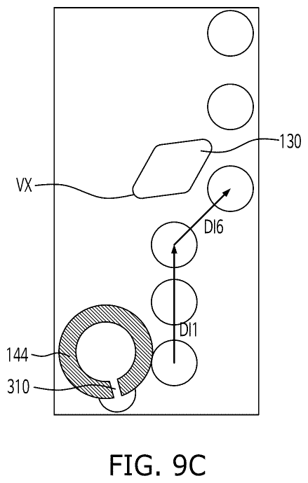

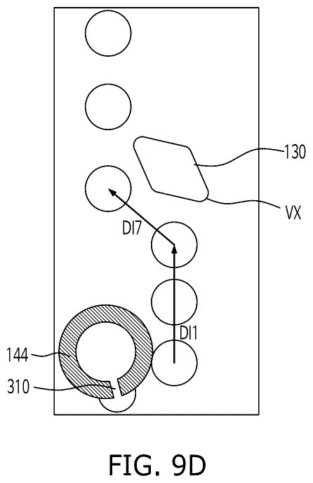

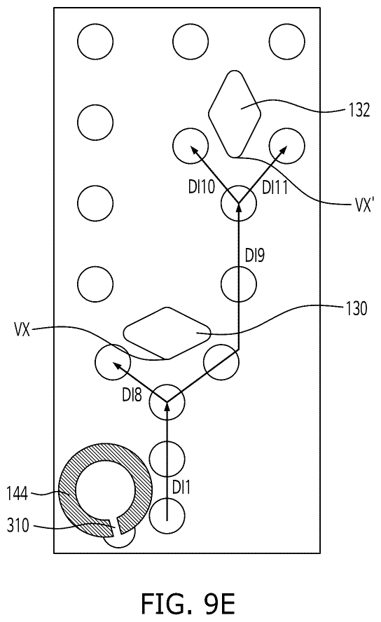

The rod 130 may change the existing path of the bubbles or disperse them along multiple paths so that a uniform flow is provided over the entire surface of the wafer 160. For example, if bubbles contact a vertex or side of the rod 130, the path of the bubbles may change, or the bubbles may split or rotate. Details will be described below with reference to FIGS. 9A through 9E.

Plates 170 and guides 172 may be disposed adjacent to the outer circumferential surface (for example, a side surface of the wafer 160 when laying flat or upper surface of the wafer when 160 when positioned as shown in FIG. 1) of the wafer 160 so as to control the flow of the bubbles. The guides 172 may be integrally formed on or attached to the surface of the plates 170 and guide the bubbles ascending along the surface of the wafer 160 toward the outside of the inner bath 110b. A group of guides 172 may be disposed between adjacent plates 170. Each guide 172 may be attached to one of the adjacent plates 179. Referring to FIG. 3, the plates 170 may be disposed horizontally at a position corresponding to the upper end of the plurality of wafers 160, and the guides 172 may separate or change the bubble path as the bubbles flow between adjacent plates 170.

Referring to FIGS. 2 and 3, the length by which the guides 172 protrudes from the surface of the plate 170 may be shorter than the distance between each of the plurality of wafers 160 or may be substantially the same as the distance between each of the plurality of wafers 160.

The wafer processing apparatus 100 may further include a cover disposed above the bath 110, and the upper surface of the plates 170 may be attached to the cover and fixed to the cover so as to be positioned adjacent to the plurality of wafers 160 when the cover is closed.

Referring to FIG. 4, the liquid in the inner bath 110b may overflow the inner bath 110b into the outer bath or may flow due to the movement of the bubbles and be introduced into a drain hole 410 in the inner bath. The liquid that overflows the inner bath 110band the liquid flowing into the drain hole 410 may be discharged to the outside through a drain pipe 420.

The liquid discharged through the drain pipe 420 may be subjected to a purification process (e.g., purified) including a pump or a filter, as needed, and may then be supplied back into the inner bath 110b through the liquid supply nozzle 184. By-products or contaminants generated during process on the wafer 160 may be removed by the purification process from the liquid that was discharged through the drain hole 410 and the drain pipe 420.

Each of the components shown in FIGS. 1 through 4, such as the gas supply unit 140, the liquid supply unit 180, the rod 130, and the support 150, may be formed in various mechanical and/or material manners depending on the shape, size, and process type of the inner bath 110b and the wafer 160. Depending on the configurations of the wafer processing apparatus 100 described above, a constant supply of a cleaning liquid and bubbles to clean the wafer 160 may be provided, the bubble path may be efficiently controlled, and the uniformity of processing for the wafer 160 throughout the entire process may be improved.

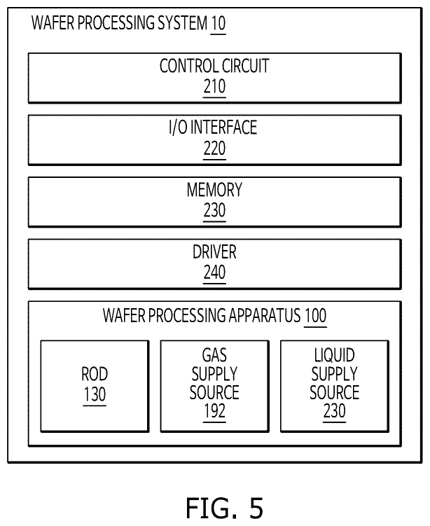

FIG. 5 is a block diagram illustrating an example of a wafer processing system 10 according to an embodiment of the present disclosure.

The wafer processing system 10 may include the wafer processing apparatus 100 and may further include a control circuit 210, an input/output interface 220, a memory 230, and a driver 240. Some components may be added or omitted, and some or all of the illustrated components may be included in the wafer processing apparatus 100.

The control circuit 210 may include a processing unit, for example, a CPU, GPU, MPU, FPGA, ASIC, or the like, without limitation. By executing code stored in the memory 230, the control circuit 210 may perform detailed control of operations of a gas supply source 192, a liquid supply source 194, and/or the driver 240 in the wafer processing apparatus 100. Through this control, bubble generation and control of the diameter (or size) of bubbles may be performed.

The input/output interface 220 may receive operational information, such as the spacing between the wafers, the processing time, and the temperature range, from a user, and deliver it to the control circuit 210, or may notify the user of results generated by the control circuit 210.

The control circuit 210 may control the driver 240 that is connected to the rod 130 so as to rotate the rod 130. This will be described in more detail with reference to FIGS. 9A through 9E.

The control circuit 210 may control the gas supply source 192 to adjust the pressure of the gas supplied to the gas supply nozzle (for example, 144 in FIGS. 1 through 4).

The control circuit 210 may control the liquid supply source 194 to adjust the pressure of the liquid supplied to the liquid supply nozzle (for example, 184 in FIGS. 1 through 4).

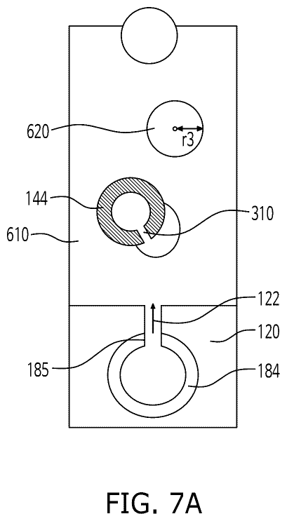

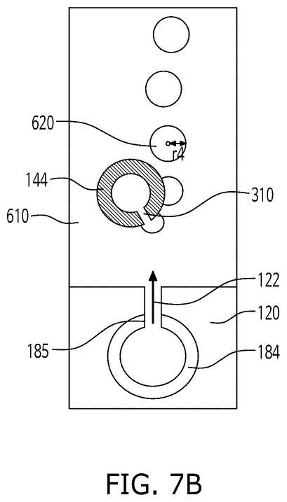

Through this, the control circuit 210 may finely control the diameter of bubbles generated by the gas supply nozzle 144, and details will be described below with reference to FIGS. 7A and 7B.

The input/output interface 220 may receive, from a user (for example, an operator of the wafer processing apparatus 100), operational information and information related to the wafer processing apparatus 100, such as the spacing between the plurality of wafers, the process time, the temperature range, the rod rotation speed, the distance between the rod 130 and the gas supply nozzle (for example, 144 in FIGS. 1 through 4), and the distance between the gas supply nozzle and the liquid supply nozzle (for example, 184 in FIGS. 1 through 4). The input/output interface 220 may provide the user with control results determined by the control circuit 210, wafer processing results, and status information (for example, elapsed time) during the wafer processing.

The memory 230 may include any type of storage medium, for example, ROM, RAM, flash memory, HDD, SSD, another semiconductor memory, or an optical disk, without limitation. The memory 230 may store or retrieve program code, operational conditions, process conditions, and various parameters and data needed for wafer processing. For example, the memory 230 may store information or data input through the input/output interface 220.

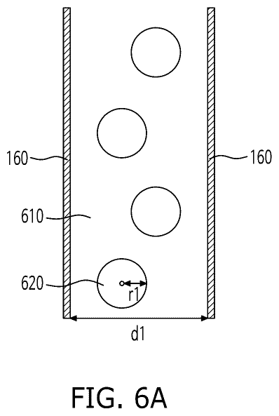

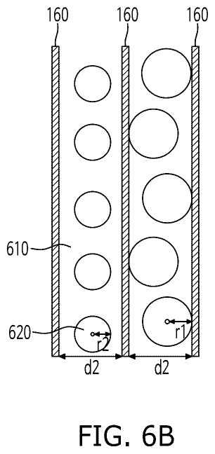

FIGS. 6A and 6B are diagrams for explaining bubble flow resistance in a bath according to the spacing between wafers and the size of the bubbles. FIGS. 6A and 6B illustrate an example of the behavior of bubbles moving in a liquid 610 between two wafers inside the wafer processing apparatus 100 described with reference to FIGS. 1 through 4.

Referring to FIG. 6A, if the distance between wafers 160 is relatively large (d1), compared to FIG. 6B, the bubble 620 may pass through the liquid 610 between the wafers 160 with relatively less friction or residence, so the flow (for example, upward movement) of the bubble may proceed smoothly.

Referring to FIG. 6B, compared to the example of FIG. 6A, if a greater number of wafers are accommodated in the wafer processing apparatus, the distance between the wafers 160 may become d2, which is smaller than d1. In this case, if the bubble 620 retains its previously maintained radius r1, the bubble 620 may come into excessive contact with the surface of the wafer 160 or block the passage, thereby significantly increasing the flow resistance of the bubble. For instance, the bubble 620 may move as if rubbing against the wafer 160 and may fail to rise at its original speed, instead ascending at a lower speed.

In contrast, if the radius of the bubble 620 is reduced to r2, the flow resistance of the bubble 620 may decrease, and the bubble 620 may ascend more smoothly, thereby facilitating various processes such as cleaning. Therefore, it is helpful to adjust the size of the bubbles 620 according to the spacing between the wafers 160.

FIGS. 7A and 7B are diagrams illustrating an example in which the size of the bubbles within the bath is adjusted.

Referring to FIGS. 5, 7A, and 7B, the liquid supply nozzle 184 may supply liquid in the direction of the gas supply hole 310 of the gas supply nozzle 144. For example, referring also to FIGS. 1 through 4, the liquid supply nozzle 184 may include a plurality of liquid supply holes 185, and the gas supply nozzle 144 may include a plurality of gas supply holes 310. Each of the plurality of liquid supply holes 185 may supply liquid in a direction corresponding to each of the plurality of gas supply holes 310.

The control circuit 210 may control the liquid supply source 194 configured to supply the liquid 610 to the liquid supply nozzle 184 so as to adjust the pressure of the liquid 610 supplied from the liquid supply source 194 to the liquid supply nozzle 184, thereby adjusting the diameters (or size/volume) of the bubbles 620 generated by the gas.

For example, if the control circuit 210 raises the pressure of the liquid 610 supplied to the liquid supply nozzle 184, the pressure of the liquid 610 supplied in the direction of the gas supply hole 310 increases. Then, before the bubble grows beyond a certain size, the bubble may easily separate from the gas supply hole 310, thus decreasing the size (or diameter) of the bubble.

In contrast, if the control circuit 210 lowers the pressure of the liquid 610 supplied to the liquid supply nozzle 184, the pressure of the liquid 610 supplied in the direction of the gas supply hole 310 decreases. Then, the bubble may grow beyond a certain size before separating from the gas supply hole 310, thus increasing the size (or diameter) of the bubble.

Referring to FIG. 7A, if the pressure of the liquid, supplied through the liquid supply nozzle 184 (or through the liquid supply nozzle 184 and the guide holes 122 of the liquid supply guide 120) is low, the size of the bubble 620 may increase to r3. If the diameter of the bubble 620 becomes larger, in a situation where wafers 160 are appropriately spaced, the buoyancy and flow mixing effect of the bubble may be maximized.

Referring to FIG. 7B, if the pressure of the liquid supplied through the liquid supply nozzle 184 (or through the liquid supply nozzle 184 and the guide holes 122 of the liquid supply guide 120) becomes higher, the size of the bubble 620 may decrease to r4. If the diameter of the bubble 620 is reduced, the bubble 620 may move smoothly and cause less surface friction even in a process where the wafers 160 are closely spaced. This is advantageous in maintaining a constant flow speed and mixing effect even if the spacing is reduced due to an increased number of wafers 160, and allows stable control of the terminal velocity of the bubble 620.

In an embodiment, the control circuit 210 may control the liquid supply source 194 so that, when the spacing between each of the plurality of wafers 160 narrowed, the pressure of the liquid supplied from the liquid supply source 194 to the liquid supply nozzle 184 increases, thereby adjusting (reducing) the diameter (or size/volume) of the bubble 620.

In another embodiment, the control circuit 210 may control the liquid supply source 194 so that, as the distance between the first rod 130 and the gas supply nozzle 144 becomes smaller, the pressure of the liquid supplied from the liquid supply source 194 to the liquid supply nozzle 184 increases, thereby adjusting (reducing) the diameter of the bubble 620.

In another embodiment, by controlling the liquid supply source 194 to adjust the pressure of the liquid 610 supplied to the liquid supply nozzle 184, the control circuit 210 may adjust the diameter of the bubble 620 so that the diameter of the bubbles 620 is smaller than the distance between the liquid supply nozzle 184 and the gas supply nozzle 144. As such, the liquid supply nozzle 184 may not become a mechanical/spatial obstruction to the bubbles 620 generated by the gas supply nozzle 144.

Through the configurations described with reference to FIGS. 7A and 7B, the uniformity and/or productivity of the wafer cleaning process may be improved by appropriately matching the size of the bubble 620 to the current configuration. Because the size of the bubble 620 may be controlled by changing the pressure or flow rate, it is possible to reduce recirculation flow and suppress the spread of contaminants by implementing an optimal bubble size according to the process situation or conditions.

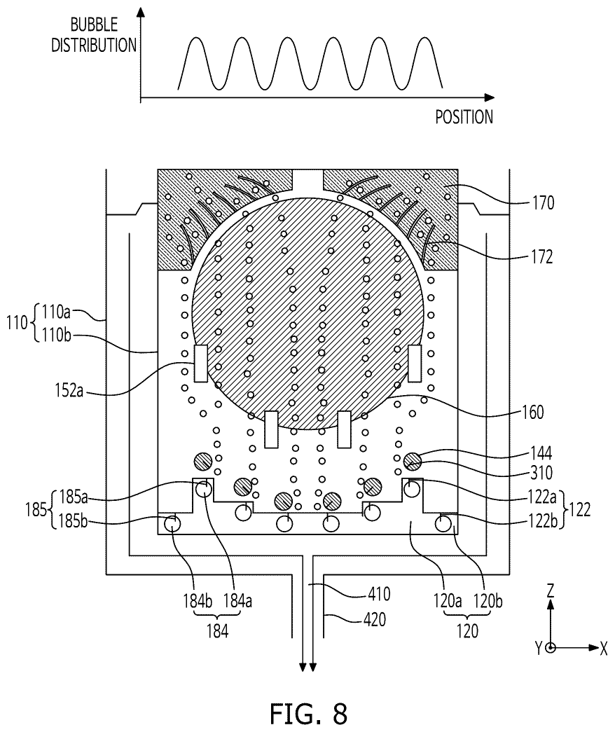

FIG. 8 is a diagram illustrating an example of the distribution of bubbles according to position within the inner bath 110b.

Referring to FIG. 8, in the absence of the rod 130, it may be observed that the bubbles are not uniformly distributed within the inner bath. If the bubbles concentrate in some regions, the flow may be enhanced only on the wafer surface in those regions, making it difficult to obtain a sufficient cleaning effect in other regions. Such an uneven distribution of bubbles may cause process variation and allow contaminants to remain stagnant in certain regions, thereby reducing overall process efficiency.

FIGS. 9A through 9E are diagrams illustrating an example in which the path of the bubbles is changed by the rod 130.

The rod 130 is arranged to selectively split or redirect the path of the moving bubbles to overcome the problem described with reference to FIG. 8, and may be configured so as to be rotatable. In FIGS. 9A through 9E, for ease of description, the trajectory of the bubbles is depicted in two dimensions, but it may actually involve a three-dimensional trajectory. Referring to FIGS. 9A through 9E, the rod 130 may change at least part of the path of bubbles ascending along a first path (DI1). In an embodiment, the rod 130 may have a polygonal cross section, and when the bubbles contact a vertex (VX), the bubbles ascending along the first path (DI1) may split and move along multiple paths, or move along a different path. For example, by contacting the vertex (VX) of the polygon, at least part of the path of at least some of the bubbles may be changed to follow at least one of the sides of the polygon connected to the vertex (VX).

Referring to FIG. 9A, the rod 130 may split at least some of the bubbles into a second path (DI2) and a third path (DI3), such that a first portion of the bubbles ascend along the second path (DI2) and a second portion of the bubbles ascend along the third path (DI3) different from the second path (DI2). For example, while the bubbles ascend along the first path (DI1), by contacting the vertex (VX) of the rod 130, the bubbles may be split into the second path (DI2) and the third path (DI3). Such splitting of the path may prevent the bubbles from converging in a particular region, contributing to supplying a uniform flow over the entire wafer surface.

Referring to FIG. 9B, as the rod 130 rotates, the range in which the path of the bubbles is split may widen further. By virtue of the rotation of the rod 130, at least part of the bubbles may be split into a fourth path (DI4) and a fifth path (DI5) such that a first portion of the bubbles ascend along the fourth path (DI4) and a second portion of the bubbles ascend along the fifth path (DI5) different from the fourth path (DI4). Because of the rotation of the rod 130, the moving path of the bubbles may be extended to the fourth path (DI4) and the fifth path (DI5). As a result, the bubbles may spread to various positions in the inner bath, improving process uniformity.

Referring to FIGS. 9C and 9D, the rod 130 may change the path of the bubbles into a single path without splitting them. If the bubbles redirect from the first path (DI1) to the sixth path (DI6) or the seventh path (DI7), the bubbles may be moved so as to concentrate in a certain region, aligning with the purpose of localized concentration. This approach may be more useful in situations where local intensive cleaning or removal of contaminants at a specific region is needed.

Referring to FIG. 9E, an additional rod 132 is provided, allowing a single bubble to change the path multiple times. The additional rod 132 may be placed above the rod 130, and may further change part of the path of the bubbles that has already been split by the rod 130. For example, the path of the bubbles may be split from the first path (DI1) to the eighth path (DI8) and the ninth path (DI9) by the rod 130, and subsequently, upon passing the vertex of the rod 132, the bubbles moving along the ninth path (DI9) may be split into a tenth path (DI10) and an eleventh path (DI11). Through such a multistage splitting process, the bubbles may be uniformly dispersed over the entire wafer surface, and vortex flows may be suppressed, thereby efficiently removing contaminants generated during processing.

The angular position of the rods 130 and 132 shown in and described with reference to FIGS. 9A through 9E may be controlled by the control circuit 210 of FIG. 5. By controlling the driver 240 in FIG. 5 to rotate the rods 130 and 132, the control circuit 210 may change the angular position of the rods 130 and 132. For example, by controlling the driver 240 so as to rotate the rod, the control circuit 210 may, at a first time, change at least part of the path of the bubbles from the first path (DI1) to at least one of a second path (DI2) or a third path (DI3), and, at a second time different from the first time, change at least part of the path of the bubbles from the first path (DI1) to at least one path different from the second path (DI2) and the third path (DI3). In another example, the control circuit 210 may control the driver 240 so as to rotate the rod 130 at a constant angular velocity. As a result, the bubbles may be uniformly dispersed.

FIG. 10 illustrates an example in which the rod 130 and the support 150 are integrated.

The rod 130 may be formed integrally with the support 150 and extend from the lower portion of the support 150. In this way, it is not necessary to fix the rod 130 separately, and even if the wafer 160 is transported inside the bath 110, the position of the rod 130 may be stably maintained. As a result, the bubble dispersing effect by the rod 130 may be provided consistently, and the robustness of the arrangement structure may be enhanced, thereby reducing process variation.

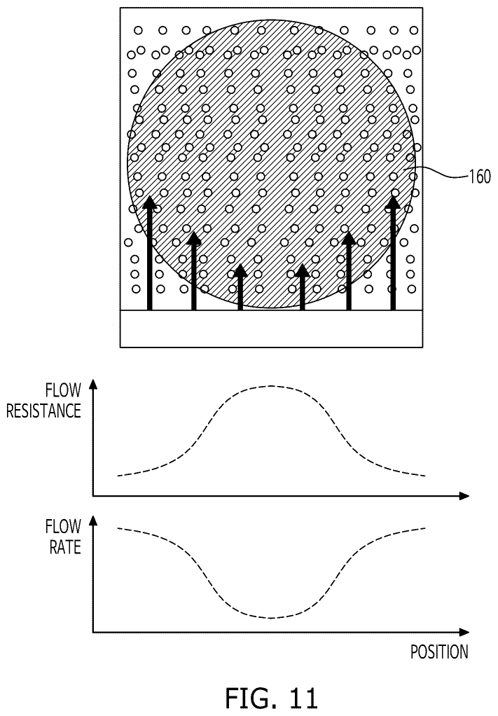

FIG. 11 is a diagram showing that flow resistance increases toward the center of the wafer 160, causing a decrease in flow speed accordingly. If gas is supplied or liquid is introduced inside the bath, the flow path of the fluid at the center of the wafer 160 may become narrower or more complex compared to the edge of the wafer 160, causing relatively slower or more highly resistant flow near the center. Consequently, sufficient cleaning solution may not flow or uniform bubbles may not reach the central area of the wafer 160, and liquid in the outer portion of the inner bath may not overflow into the outer bath but instead flow back into the central portion of the inner bath, reducing process efficiency. This problem may vary according to various process conditions (for example, wafer diameter, bath size, liquid viscosity), and to ensure process uniformity, there is a need for a means to induce sufficient flow even in the center of the wafer 160.

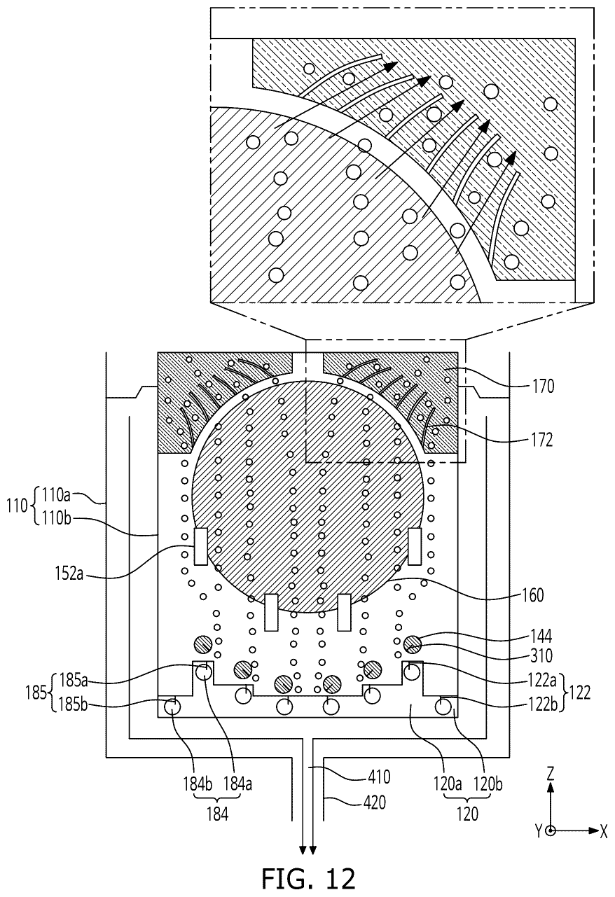

FIG. 12 is a diagram illustrating an example of guiding the bubbles by using the guides 172 and the plates 170.

The plates 170 may be disposed adjacent to the outer circumferential surface of the wafer 160 and may be disposed parallel to a major surface of each of the plurality of wafers 160 (e.g., parallel to a bottom or upper planar surface of a wafer). The plates 170 may be arranged spaced apart from the plurality of wafers 160 so as not to contact the outer circumferential surface of the plurality of wafers 160, leaving a predetermined gap. The example shown in FIG. 12 is not limited, and the plates 170 may be formed and disposed so as to cover the entire outer circumferential surface of the plurality of wafers 160 or to partially cover the outer circumferential surface.

The guides 172 may guide the path of the bubbles in a specific direction. For example, the guides 172 may be disposed adjacent to the outer circumferential surface of each of the plurality of wafers 160 and guide bubbles ascending along the surface the plurality of wafers 160 to move outward from the bath 110.

The guide 172s may each have a curved shape, a polygonal shape, a ring shape, and so on, as needed. The guides 172 may be formed with a certain curvature corresponding to the shape of the outer circumferential surface of the wafer 160. For example, the plates 170 may be manufactured to have nearly the same planar shape as that of the wafer 160, installed to maintain a gap (for example, 2-5 mm) from the wafer 160. The guides 172 may be placed adjacent to the perimeter of the wafer 160 to guide the flow of bubbles outward from the wafer 160.

The guides 172 may be disposed on the surface of the plates 170. For example, the guides 172 may be formed in a shape protruding from the plates 170, and while ascending from below, the bubbles may move along the inclined surface or edge of the guides 172 and be concentrated or dispersed toward a specific region, according to each guide. In some embodiments, by varying the number of guides 172, the placement angle, height, etc., the bubbles may flow along diverse paths, further reducing the possibility of vortex flows and alleviating the problem of contaminants accumulating in a specific region. The size and shape of the guides 172 may be selected according to the process objectives or the internal design of the bath 110, and may be formed in various shapes such as a hemispherical shape, a polyhedral shape, or a simple flat structure, for example.

Thus, by disposing the plates 170 and the guides 172 above and/or around the wafer 160, the flow field formed within the bath 110 becomes more uniform, and the difference in flow speed or flow resistance between the center portion and the peripheral portion of each wafer 160 may be effectively suppressed. Consequently, the overall process uniformity across each wafer 160 may increase, and the efficiency of removing contaminant particles or by-products may be improved, enhancing the productivity of processes using the wafer processing apparatus.

The present disclosure is not limited by the above embodiments and the accompanying drawings. Various substitutions, modifications, and changes can be made by those of ordinary skill in the art without departing from the technical spirit of the present disclosure, all of which also fall within the scope of the present disclosure.

What is claimed is:

1. A semiconductor wafer processing apparatus comprising:
a bath configured to accommodate a liquid used to process a plurality of semiconductor wafers;
a liquid supply nozzle configured to supply the liquid into the bath;
a gas supply nozzle disposed below the plurality of semiconductor wafers and configured to supply a gas into the bath to generate bubbles with the liquid supplied;
a first rod disposed above the gas supply nozzle and configured to change a path of a portion of the bubbles generated by the gas and ascend within the bath along a first path; and
a support connected to the bath and configured to support the plurality of semiconductor wafers in a configuration with semiconductor wafers of the plurality of semiconductor wafers spaced apart from each other above the first rod.

2. The semiconductor wafer processing apparatus according to claim 1, wherein:
the first rod has a polygon cross section; and
the first rod is configured to change the path of the portion of the bubbles through the portion of the bubbles contacting a vertex of the polygon and traveling along a portion of a side of the polygon connected to the vertex of the polygon.

3. The semiconductor wafer processing apparatus according to claim 2, wherein:
the first rod has a rhombus shaped cross section; and
a first diagonal and a second diagonal of the rhombus shaped cross section have different lengths from each other.

4. The semiconductor wafer processing apparatus according to claim 1, wherein:
the portion of the bubbles is a first portion of the bubbles; and
the first rod is further configured to split a second portion of the bubbles into a second path and a third portion of the bubbles into a third path such that the second portion of the bubbles ascend along the second path and the third portion of the bubbles ascend along the third path different from the second path.

5. The semiconductor wafer processing apparatus according to claim 4, further comprising:
a second rod disposed above the first rod and configured to change a path of at least some of the third portion of the bubbles that ascend along the third path.

6. The semiconductor wafer processing apparatus according to claim 1, wherein
the first rod is formed integrally with the support and extends from a lower portion of the support.

7. The semiconductor wafer processing apparatus according to claim 1, wherein:
the gas supply nozzle has a gas supply hole configured to supply the gas; and
the liquid supply nozzle is configured to supply the liquid in a direction toward the gas supply hole formed in the gas supply nozzle.

8. The semiconductor wafer processing apparatus according to claim 7, wherein:
the liquid supply nozzle includes a plurality of liquid supply holes;
the gas supply nozzle includes a plurality of gas supply holes; and
each liquid supply hole of the plurality of liquid supply holes is configured to supply the liquid in a direction toward a corresponding gas supply hole of the plurality of gas supply holes.

9. The semiconductor wafer processing apparatus according to claim 1, further comprising:
guides disposed within the bath,
wherein the support is configured to support the plurality of semiconductor wafers such that an outer circumferential surface of each of the plurality of semiconductor wafers is adjacent to the guides, and
wherein the guides are configured to guide bubbles ascending along surfaces of each of the plurality of semiconductor wafers to move outward from the bath.

10. The semiconductor wafer processing apparatus according to claim 9, further comprising:
plates disposed adjacent to guides, respectively,
wherein the support is configured to support the plurality of semiconductor wafers such that an outer circumferential surface of each of the plurality of semiconductor wafers is disposed adjacent to the guides and planar surfaces of the plurality of semiconductor wafers are parallel to the plates.

11. The semiconductor wafer processing apparatus according to claim 10, wherein
the support is configured to support the plurality of semiconductor wafers with the plates disposed spaced apart from the outer circumferential surface of each of the plurality of semiconductor wafers by a predetermined gap.

12. The semiconductor wafer processing apparatus according to claim 1, wherein the plurality of semiconductor wafers are spaced apart from one another in a first direction and the liquid supply nozzle comprises:
a first liquid supply nozzle formed to extend in the first direction and disposed below the plurality of semiconductor wafers; and
a second liquid supply nozzle formed to extend in the first direction and disposed below the plurality of semiconductor wafers at a location further from the center of the bath than the first liquid supply nozzle.

13. The semiconductor wafer processing apparatus according to claim 12, wherein
a first diameter of a first liquid supply hole through which the first liquid supply nozzle supplies the liquid into the bath is smaller than a second diameter of a second liquid supply hole through which the second liquid supply nozzle supplies the liquid into the bath.

14. A semiconductor wafer processing system comprising:
a bath configured to accommodate a liquid for processing a plurality of semiconductor wafers;
a support connected to the bath and configured to support the plurality of semiconductor wafers in a configuration with wafers of the plurality of semiconductor wafers spaced apart from one another;
a liquid supply nozzle configured to supply the liquid into the bath;
a gas supply nozzle disposed below the plurality of semiconductor wafers and configured to supply a gas into the bath to generate bubbles with the liquid;
a rod disposed above the gas supply nozzle and configured to change a path of bubbles that are generated by the gas and ascend within the bath along a first path that intercepts the rod;
a driver configured to rotate the rod; and
a control circuit configured to control the driver to rotate the rod to change the path of bubbles contacting the rod at a first time point from the first path to at least one of a second path and a third path and change the path of the bubbles contacting the rod at a second time point from the first path to at least one of a fourth path and a fifth path, wherein the second time point is different from the first time point and each of the fourth path and the fifth path is different from the second path and the third path.

15. The semiconductor wafer processing system according to claim 14, wherein
the control circuit is further configured to control the driver to rotate the rod at a constant angular velocity.

16. The semiconductor wafer processing system according to claim 14, wherein
the liquid supply nozzle is configured to supply the liquid in a direction toward a gas supply hole formed in the gas supply nozzle,
the semiconductor wafer processing system further comprises a liquid supply source configured to supply the liquid to the liquid supply nozzle, and
the control circuit is further configured to control the liquid supply source to adjust a pressure of the liquid supplied from the liquid supply source to control the diameter of the bubbles generated by the gas.

17. The semiconductor wafer processing system according to claim 16, wherein
the control circuit is further configured to control the diameter of the bubbles based on a spacing of the plurality of semiconductor wafers such that as the spacing between each semiconductor wafer of the plurality of semiconductor wafers is narrower, the pressure of the liquid supplied from the liquid supply source to the liquid supply nozzle increases, thereby reducing the diameters of the bubbles.

18. The semiconductor wafer processing system according to claim 16, wherein
the control circuit is further configured to control the diameter of the bubbles based on a distance between the rod and the gas supply nozzle such that as a distance between the rod and the gas supply nozzle becomes smaller, the pressure of the liquid supplied from the liquid supply source to the liquid supply nozzle increases, thereby reducing the diameters of the bubbles.

19. The semiconductor wafer processing system according to claim 16, wherein
the control circuit is further configured to control the diameter of the bubbles by adjusting the pressure of the liquid supplied to the liquid supply nozzle such that the diameters of the bubbles are smaller than a distance between the liquid supply nozzle and the gas supply nozzle.

20. A semiconductor wafer processing apparatus comprising:
a bath configured to contain a liquid used to process a plurality of semiconductor wafers;
a gas supply nozzle configured to supply a gas into the bath through a gas supply hole;
a liquid supply nozzle configured to supply the liquid into the bath in a direction toward the gas supply hole, wherein the gas causes bubbles to form in the liquid;
a rod disposed above the gas supply nozzle and configured to change a path of a portion of the bubbles that ascend within the bath;
plates disposed within the bath at an upper portion of the bath;
guides disposed on surfaces of the plates and configured to guide bubbles ascending in the bath to move outward from the bath; and
a support connected to the bath and configured to support the plurality of semiconductor wafers in a configuration with semiconductor wafers of the plurality of semiconductor wafers spaced apart from each other with a side surface of each of the plurality of semiconductor wafers being disposed spaced apart from the plates by a predetermined gap, and an planar surface of each of the plurality of semiconductor wafers being parallel to the guides.
